(19) United States
(12) Patent Application Publication
(10) Pub. No.: US 2016/0314975 A1
(43) Pub. Date: Oct. 27, 2016

(54) DIFFUSION AGENT COMPOSITION

(71) Applicant: TOKYO OHKA KOGYO CO., LTD., Kawasaki-shi (JP)

(72) Inventor: Yoshihiro SAWADA, Kawasaki-shi (JP)

(21) Appl. No.: 15/131,698

(22) Filed: Apr. 18, 2016

(30) Foreign Application Priority Data
Apr. 21, 2015 (JP) 2015-087064
Mar. 9, 2016 (JP) 2016-046013

(51) Int. Cl. H01L 21/225

(52) U.S. Cl. CPC H01L 21/2254

(57) ABSTRACT

A diffusion agent composition that, even when coated on a semiconductor substrate in a nano-scale thickness, allows an impurity diffusion component to be well diffused into the semiconductor substrate. The diffusion agent composition includes an impurity diffusion component and a silicon compound represented by R₄₋ₙSi(NCO)ₙ in which R represents a hydrocarbon group and n is an integer of 3 or 4, the silicon compound is capable of being hydrolyzed to produce a silanol group, and the water content of the diffusion agent composition is not more than 0.05% by mass.

This application claims the benefit priority to Japanese Patent Application No. 2015-087064, filed Apr. 21, 2015; and Japanese Patent Application No. 2016-046013, filed on Mar. 9, 2016, the contents of which are incorporated herein by reference.

### BACKGROUND OF THE INVENTION

1. Field of the Invention

The present invention relates to a diffusion agent composition containing an impurity diffusion component and a hydrolyzable silane compound having a predetermined structure.

2. Related Art

A semiconductor substrate used in a semiconductor element such as a transistor, a diode and a solar battery is manufactured by diffusing impurity diffusion components such as phosphorus and boron thereinto.

For example, as a method for manufacturing such a semiconductor substrate, a method of coating a diffusion agent composition containing an impurity diffusion component such as an organic phosphorus compound, a polymer for thickening, an organic solvent, and water onto a semiconductor substrate, followed by heating the coating at a temperature above 1000° C. for an extended period of time, for example for 10 hours, to diffuse the impurity diffusion component into the semiconductor substrate has been known (see Patent Document 1).

Patent Document 1: Japanese Unexamined Patent Application, Publication No. 2005-347306

### SUMMARY OF THE INVENTION

A semiconductor substrate may have a three-dimensional steric structure on a surface thereof. An example of the three-dimensional steric structure is a nano-scale three-dimensional structure like a steric structure for the formation of multigate elements called Fin-FETs, the steric structure comprising a plurality of source fins, a plurality of drain fins, and gates perpendicular to the fins.

In this case, in order to uniformly diffuse an impurity diffusion component from a coating film of a diffusion agent composition in the surface of a semiconductor substrate, additional formation of a coating film having a uniform thickness, for example, also on the surface of side walls of concaves in the steric structure is desired. To this end, uniform coating of the diffusion agent composition in a nano-scale thickness on the whole substrate surface, as well as superior diffusion of the impurity diffusion component from the thin coating film thus formed are necessary.

As disclosed in Patent Document 1, however, in a diffusion agent composition containing a polymer for thickening, it is difficult to uniformly coat the diffusion agent composition on a semiconductor substrate surface in a nano-scale thickness.

Further, when the diffusion agent composition disclosed in Patent Document 1 is used, even if the diffusion agent composition can be thinly coated on the semiconductor substrate surface, the impurity diffusion component may not be well diffused depending on the composition of the diffusion agent composition.

The present invention has been made in view of the above problems, and an object thereof is to provide a diffusion agent composition that, even when coated on a semiconductor substrate in a nano-scale thickness, allows superior diffusion of the impurity diffusion component into the semiconductor substrate.

The present inventors have found that the above problems can be solved by incorporating an impurity diffusion component (A) and a Si compound (B) of a predetermined structure containing an isocyanate group and by regulating the water content of the diffusion agent composition to not more than 0.05% by mass, leading to the completion of the present invention.

Specifically, the present invention relates to a diffusion agent composition for impurity diffusion into a semiconductor substrate, the diffusion agent composition comprising an impurity diffusion component (A) and a Si compound (B) represented by the following formula (1):

R₄₋ₙSi(NCO)ₙ (1)

wherein R represents a hydrocarbon group and n is an integer of 3 or 4,
the Si compound (B) being hydrolyzable to produce a silanol group, and

the water content of the diffusion agent composition being not more than 0.05% by mass.

The present invention can provide a diffusion agent composition that, even when coated onto a semiconductor substrate in a nano-scale thickness, allows superior diffusion of the impurity diffusion component into the semiconductor substrate.

### DETAILED DESCRIPTION OF THE INVENTION

### Diffusion Agent Composition

The diffusion agent composition contains an impurity diffusion component (A) and a Si compound (B) that is hydrolyzable to produce a silanol group. In the present specification, the Si compound (B) that can produce a silanol group is also referred to as a hydrolyzable silane compound (B). Essential and optional components contained in the diffusion agent composition and a process for preparing a diffusion agent composition will be described hereinafter.

### [Impurity Diffusion Component (A)]

As the impurity diffusion component (A), any component having conventionally been used for doping a semiconductor substrate can be used without particular limitation; and can be either an n-type dopant or a p-type dopant. Elementary substances such as phosphorus, arsenic, and antimony and compounds containing these elements can be exemplified as the n-type dopant. Elementary substances such as boron, gallium, indium, and aluminum and compounds containing these elements can be exemplified as the p-type dopant.

The impurity diffusion component (A) is preferably a phosphorus compound, a boron compound, or an arsenic compound which are easily available and easily handled. Preferred phosphorus compounds include phosphoric acid, phosphorous acid, hypophosphorous acid, polyphosphoric acid, and diphosphorus pentaoxide, phosphorous acid esters, phosphoric acid esters, phosphorous acid tris (trialkylsilyl), and phosphoric acid tris (trialkylsilyl). Preferred boron compounds include boric acid, metaboric acid, boronic acid, perboric acid, hypoboric acid, diboron trioxide, and trialkyl borate. Preferred arsenic compounds include arsenic acid and trialkyl arsenate.

Preferred phosphorus compounds include phosphorous acid esters, phosphoric acid esters, tris(trialkylsilyl) phosphite, and tris(trialkylsilyl) phosphate. Among these, trimethyl phosphate, triethyl phosphate, trimethyl phosphite, triethyl phosphite, tris(trimethoxysilyl) phosphate, and tris(trimethoxysilyl) phosphite are preferred. Trimethyl phosphate, trimethyl phosphite, and tris(trimethylsilyl) phosphate are more preferred, and trimethyl phosphate is particularly preferred.

Preferred boron compounds include trimethylboron, triethylboron, trimethyl borate, and triethyl borate.

Preferred arsenic compounds include arsenic acid, triethoxyarsenic, and tri-n-butoxyarsenic.

The content of the impurity diffusion component (A) in the diffusion agent composition is not particularly limited. The content of the impurity diffusion component (A) in the diffusion agent composition is preferably such that an amount (moles) of elements acting as a dopant in a semiconductor substrate, such as phosphorus, arsenic, antimony, boron, gallium, indium, and aluminum contained in the impurity diffusion component (A) is 0.01 to 5 times, and more preferably such that said amount is 0.05 to 3 times, of the number of moles of Si contained in the hydrolyzable silane compound (B).

### [Hydrolyzable Silane Compound (B)]

The diffusion agent composition contains a hydrolyzable silane compound (B). The hydrolyzable silane compound (B) is a compound represented by the following formula (1):

R₄₋ₙSi(NCO)ₙ (1)

wherein R represents a hydrocarbon group; and n is an integer of 3 or 4.

For this reason, when the diffusion agent composition of the present application is coated on a semiconductor substrate to form a thin film, the hydrolyzable silane compound is hydrolytically condensed mainly by moisture in an atmosphere of a coating environment to form an extremely thin film based on a silicon oxide within the coating film.

The hydrocarbon group, i.e. R in the formula (1), is not particularly limited unless the object of the present invention is impeded. Aliphatic hydrocarbon groups having 1 to 12 carbon atoms, aromatic hydrocarbon groups having 1 to 12 carbon atoms, and aralkyl groups having 1 to 12 carbon atoms are preferred as R.

Examples of suitable aliphatic hydrocarbon groups having 1 to 12 carbon atoms include methyl, ethyl, n-propyl, isopropyl, n-butyl, sec-butyl, isobutyl, tert-butyl, n-pentyl, isopentyl, neopentyl, cyclopentyl, n-hexyl, cyclohexyl, n-heptyl, cycloheptyl, n-octyl, cyclooctyl, n-nonyl, n-decyl, n-undecyl, and n-dodecyl groups.

Examples of suitable aromatic hydrocarbon groups having 1 to 12 carbon atoms include phenyl, 2-methylphenyl, 3-methylphenyl, 4-methylphenyl, 2-ethylphenyl, 3-ethylphenyl, 4-ethylphenyl, α-naphthyl, β-naphthyl, and biphenylyl groups.

Examples of suitable aralkyl groups having 1 to 12 carbon atoms include benzyl, phenetyl, α-naphthylmethyl, β-naphthylmethyl, 2-α-naphthylethyl, and 2-β-naphthylethyl groups.

Among the above-described hydrocarbon atoms, methyl and ethyl groups are preferred, and a methyl group is more preferred.

Among the hydrolyzable silane compounds (B) represented by the formula (1), tetraisocyanatesilane, methyltriisocyanatesilane, and ethyltriisocyanatesilane are preferred, and tetraisocyanatesilane is more preferred.

The content of the hydrolyzable silane compound (B) in the diffusion agent composition is preferably 0.001 to 3.0% by mass, more preferably 0.01 to 1.0% by mass, in terms of a Si concentration. When the diffusion agent composition contains the hydrolyzable silane compound (B) at this concentration, external diffusion of the impurity diffusion component (A) from the thin coating film formed using the diffusion agent composition can be well suppressed, and the impurity diffusion component can be diffused well and uniformly into the semiconductor substrate.

### [Organic Solvent (S)]

The diffusion agent composition usually contains an organic solvent (S) as a solvent for allowing formation of a thin coating film. The type of the organic solvent (S) is not particularly limited as long as the object of the present invention is not impeded.

The diffusion agent composition contains the hydrolyzable silane compound (B) and thus is preferably substantially free from water. The expression “the diffusion agent composition is preferably substantially free from water” means that the diffusion agent composition does not contain water in such an amount that the hydrolysis proceeds to a level that impedes the object of the present invention.

Specific examples of organic solvents (S) include sulfoxides such as dimethylsulfoxide; sulfones such as dimethylsulfone, diethylsulfone, bis(2-hydroxyethyl)sulfone, and tetramethylenesulfone; amides such as N,N-dimethylformamide, N-methylformamide, N,N-dimethylacetamide, N-methylacetamide, and N,N-diethylacetamide; lactams such as N-methyl-2-pyrrolidone, N-ethyl-2-pyrrolidone, N-propyl-2-pyrrolidone, N-hydroxymethyl-2-pyrrolidone, and N-hydroxyethyl-2-pyrrolidone; imidazolidinones such as 1,3-dimethyl-2-imidazolidinone, 1,3-diethyl-2-imidazolidinone, and 1,3-diisopropyl-2-imidazolidinone; (poly)alkylene glycol dialkyl ethers such as ethylene glycol dimethyl ether, ethylene glycol diethyl ether, diethylene glycol dimethyl ether, diethylene glycol methyl ether, diethylene glycol diethyl ether, and triethylene glycol dimethyl ether; (poly)alkylene glycol alkyl ether acetates such as ethylene glycol monomethyl ether acetate, ethylene glycol monoethyl ether acetate, diethylene glycol monomethyl ether acetate, diethylene glycol monoethyl ether acetate, propylene glycol monomethyl ether acetate, and propylene glycol monoethyl ether acetate; other ethers such as tetrahydrofuran; ketones such as methylethyl ketone, cyclohexanone, 2-heptanone, and 3-heptanone; lactic acid alkyl esters such as methyl 2-hydroxypropionate, ethyl 2-hydroxypropionate, and ethyl lactate acetate; other esters such as methyl 3-methoxypropionate, ethyl 3-methoxypropionate, methyl 3-ethoxypropionate, ethyl 3-ethoxypropionate, ethyl ethoxyacetate, 3-methoxybutyl acetate, 3-methyl-3-methoxybutyl acetate, 3-methyl-3-methoxybutyl propionate, ethyl acetate, n-propyl acetate, i-propyl acetate, n-butyl acetate, i-butyl acetate, n-pentyl formate, i-pentyl acetate, n-butyl propionate, ethyl butyrate, n-propyl butyrate, i-propyl butyrate, n-butyl butyrate, methyl pyrubate, ethyl pyrubate, n-propyl pyrubate, methyl acetoacetate, ethyl acetoacetate, and ethyl 2-oxobutanoate; lactones such as β-propylolactone, γ-butyrolactone, and δ-pentylolactone: linear, branched, or cyclic hydrocarbons such as n-hexane, n-heptane, n-octane, n-nonane, methyloctane, n-decane, n-undecane, n-dodecane, 2,2,4,6,6-pentamethylheptane, 2,2,4,4,6,8,8-heptamethylnonane, cyclohexane, and methylcyclohexane; aromatic hydrocarbons such as benzene, toluene, naphthalene, and 1,3,5-trimethylbenzene; and terpenes such as p-menthane, diphenylmenthane, limonene, terpinene, bornane, norbornane, and pinane. These organic solvents may be used solely or as a mixture of two or more of them.

Since the diffusion agent composition contains the hydrolyzable silane compound (B), organic solvents (S) free from functional groups reactive with the hydrolyzable silane compound (B) are preferred. In particular, when the hydrolyzable silane compound (B) contains an isocyanate group, the organic solvent (S) free from functional groups reactive with the hydrolyzable silane compound (B) is preferred.

Groups reactive with the hydrolyzable silane compound (B) include both of functional groups that react directly with groups capable of producing a hydroxyl group as a result of hydrolysis, and functional groups reactive with a hydroxyl group (a silanol group) as a result of hydrolysis. Functional groups reactive with the hydrolyzable silane compound (B) include, for example, hydroxyl, carboxyl, and amino groups as well as halogen atoms.

Examples of suitable organic solvents free from functional groups reactive with the hydrolyzable silane compound (B) include, among specific examples of the above organic solvents (S), organic solvents recited as specific examples of mono ethers, chain diethers, cyclic diethers, ketones, esters, amide solvents free from an active hydrogen atom, sulfoxides, aliphatic hydrocarbon-based solvents optionally containing halogens, and aromatic hydrocarbon-based solvents.

### [Other Components]

The diffusion agent composition may contain various additives such as surfactants, antifoaming agents, pH adjustors, and viscosity modifiers as long as the object of the present invention is not impeded. Further, the diffusion agent composition may contain binder resins with a view to improving the coatability and film forming properties. Various resins may be used as the binder resin, and acrylic resins are preferred.

### [Method for Preparing Diffusion Agent Composition]

The diffusion agent composition can be prepared by prepared by mixing the above indispensable or optional components together to prepare a homogeneous solution. In the preparation of the diffusion agent composition, the impurity diffusion component (A) and the hydrolyzable silane compound (B) may also be used as a solution of the impurity diffusion component (A) and the hydrolyzable silane compound (B) previously dissolved in an organic solvent (S). The diffusion agent composition may if necessary be filtered through a filter having a desired opening diameter. Insoluble impurities are removed by the filtration treatment.

Further, as described above, the diffusion agent composition is substantially free from water. Specifically, the water content of the diffusion agent composition is not more than 0.05% by mass, and preferably not more than 0.015% by mass. When the water content of the diffusion agent composition is reduced to a value in the above range, the impurity diffusion component (A) can be diffused particularly well into the semiconductor substrate.

The water content of the diffusion agent composition can be measured by a Karl Fischer method. Alternatively, in the case of a ratio of the organic solvent (S) in the diffusion agent composition being at least 99%, the water content in the organic solvent (S) can be measured and used as the water content of the diffusion agent composition. It should however be noted that, in the case of the water content of the organic solvent (S) being 0.045 to 0.055% by mass, it is preferable not to use the water content of the organic solvent (S) and to measure the water content in the diffusion agent composition.

The water content of the diffusion agent composition can be reduced by any method without particular limitation. Examples of methods that can reduce the water content include methods using dehydrating agents such as molecular sieves, anhydrous magnesium sulfate, and anhydrous sodium sulfate, and distillation methods. The treatment that reduces the water content may be applied to the prepared diffusion agent composition, or alternatively may be applied to the organic solvent (S) or the solution of the impurity diffusion component (A) or hydrolyzable silane compound (B) in the organic solvent (S).

### <<Method for Manufacturing Semiconductor Substrate>>

A method for manufacturing a semiconductor substrate using the diffusion agent composition will be described.

A method suitable for manufacturing a semiconductor substrate comprises:

a coating step of coating a diffusion agent composition on a semiconductor substrate to form a coating film having a thickness of not more than 30 nm; and

a diffusion step of diffusing an impurity diffusion component (A) contained in the diffusion agent composition into the semiconductor substrate. The coating step and the diffusion step will be described.

### <Coating Step>

Various substrates that have hitherto been used as a target of diffusion of an impurity diffusion component may be used as the semiconductor substrate without limitation. Silicon substrates are typically used as the semiconductor substrate.

The semiconductor substrate may have a three-dimensional structure on its surface onto which the diffusion agent composition is to be applied. According to the present invention, even when the semiconductor substrate has on its surface the three-dimensional structure, particularly a three-dimensional structure having a nano-scale micropattern, the impurity diffusion component can be diffused well and uniformly into the semiconductor substrate by coating the diffusion agent composition to form a thin coating film having a thickness of not more than 30 nm on the semiconductor substrate.

The shape of the pattern is not particularly limited, however typical examples thereof include linear or curved lines or grooves of a rectangular cross section and hole shapes formed by removing a circular or rectangular cylindrical shape.

When the semiconductor substrate has on its surface a repeating pattern of a plurality of parallel lines as the three-dimensional structure, an interval between the lines may be not more than 60 nm, not more than 40 nm, or not more than 20 nm. The height of the lines may be not less than 30 nm, not less than 50 nm, or not less than 100 nm.

The diffusion agent composition is applied onto the semiconductor substrate so that the thickness of the coating film formed using the diffusion agent composition is not more than 30 nm, preferably 0.2 to 10 nm. The method for coating the diffusion agent composition is not particularly limited as long as a coating film having a desired thickness can be formed. Preferred coating methods for the diffusion agent composition include spin coating, ink jet coating, and spray coating. The thickness of the coating film is an average of thickness values measured at five or more points with an ellipsometer.

The thickness of the coating film is properly set to any desired thickness of not more than 30 nm depending upon the shape of the semiconductor substrate and an arbitrarily determined degree of diffusion of the impurity diffusion component (A).

After the application of the diffusion agent composition onto the surface of the semiconductor substrate, the surface of the semiconductor substrate is preferably rinsed with an organic solvent. The thickness of the coating film can be made further uniform by rinsing the surface of the semiconductor substrate after the formation of the coating film. In particular, when the semiconductor substrate has on its surface a three-dimensional structure, the thickness of the coating film is likely to be thick at the bottom (stepped portion) of the three-dimensional structure. However, the thickness of the coating film can be made uniform by rinsing the surface of the semiconductor substrate after the formation of the coating film.

Organic solvents that may be contained in the diffusion agent composition may be used as the organic solvent for rinsing.

### <<Diffusion Step>>

In the diffusion step, the impurity diffusion component (A) contained in the thin coating film formed on the semiconductor substrate using the diffusion agent composition is diffused into the semiconductor substrate. Any method may be used without particular limitation for the diffusion of the impurity diffusion component (A) into the semiconductor substrate as long as the impurity diffusion component (A) can be diffused from the coating film formed of the diffusion agent composition by heating.

A typical method is to heat a semiconductor substrate with a coating film of a diffusion agent composition formed thereon in a heating furnace such as an electric furnace. Conditions for heating are not particularly limited as long as the impurity diffusion component is diffused to a desired extent.

In general, after the removal of organic materials in the coating film by firing under an atmosphere of an oxidizing gas, the semiconductor substrate is heated under an atmosphere of an inert gas to diffuse the impurity diffusion component into the semiconductor substrate.

Heating for the removal of the organic materials by firing is preferably carried out at a temperature of approximately 300 to 1000° C., more preferably 400 to 800° C., preferably for 1 to 120 min, more preferably for 5 to 60 min.

Heating for the diffusion of the impurity diffusion component is preferably carried out at 800 to 1400° C., more preferably at 800 to 1200° C., preferably for 1 to 120 min, more preferably for 5 to 60 min.

Further, heating in diffusing the impurity diffusion component (A) into the semiconductor substrate may be carried out by one or more methods selected from the group consisting of lamp annealing methods, laser annealing methods, and microwave irradiation methods.

Lamp annealing methods include rapid thermal annealing methods and flash lamp annealing methods.

The rapid thermal annealing method is a method that includes raising the temperature of the surface of a semiconductor substrate coated with a diffusion agent composition to a predetermined diffusion temperature at a high temperature rise rate by heating with a lamp, then holding a predetermined diffusion temperature for a short period of time, and then rapidly cooling the surface of the semiconductor substrate.

The flash lamp annealing method is a heat treatment method that includes irradiating the surface of a semiconductor substrate with flash light using a xenon flash lamp or the like to raise the temperature of only the surface of the semiconductor substrate coated with a diffusion agent composition to a predetermined diffusion temperature in a short period of time.

The laser annealing method is a heat treatment method that includes irradiating the surface of a semiconductor substrate with various laser beams to raise the temperature of only the surface of the semiconductor substrate coated with a diffusion agent composition to a predetermined diffusion temperature in an extremely short period of time.

The microwave irradiation method is a heat treatment method that includes irradiating the surface of a semiconductor substrate with microwaves to raise the temperature of only the surface of the semiconductor substrate coated with a diffusion agent composition to a predetermined diffusion temperature in an extremely short period of time.

When lamp annealing methods, laser annealing methods, microwave irradiation methods and the like are used, the diffusion temperature in the diffusion of the impurity diffusion component is preferably 600 to 1400° C., more preferably 800 to 1200° C. After the temperature of the substrate surface has reached a diffusion temperature, the diffusion temperature may be held for a desired period of time. The period time for which a predetermined diffusion temperature is held is preferably short as long as the impurity diffusion component is well diffused.

In the diffusion step, the temperature rise rate at which the temperature of the substrate surface is heated to a desired diffusion temperature is preferably not less than 25° C./sec. The temperature rise rate is preferably as high as possible as long as the impurity diffusion component is well diffused.

Furthermore, formation of a semiconductor element employing the semiconductor substrate manufactured by the method of the present invention may require high concentration diffusion of the impurity diffusion component in a shallow region from the semiconductor substrate surface, depending on its structure.

In this case, in the above impurity diffusion method, a temperature profile of rapidly raising temperature of the substrate surface to a predetermined temperature, followed by rapidly cooling the semiconductor substrate surface is preferably adopted. The heat treatment employing such a temperature profile is called spike annealing.

In the spike annealing, time for holding at the predetermined diffusion temperature is preferably not more than 1 sec. The diffusion temperature is preferably 950 to 1050° C. When the spike annealing is carried out at the diffusion temperature for the holding time, the impurity diffusion component can easily be diffused in a region of a small depth from the surface of the semiconductor substrate.

In the spike annealing, the period of time for which the predetermined diffusion temperature is held is preferably not more than 1 sec. The diffusion temperature is preferably 950 to 1050° C. By the spike annealing at such a diffusion temperature for such a holding time, the impurity diffusion component can be well diffused in a shallow region from the semiconductor substrate surface.

As described above, the use of the diffusion agent composition according to the present invention allows superior diffusion of an impurity diffusion component into a semiconductor substrate even in the case of coating the diffusion agent composition onto the semiconductor substrate in a nano-scale thickness.

Although the mechanism of the above effect has not been elucidated yet, the mechanism can be considered as follows.

When the diffusion agent composition of the present invention is coated onto a semiconductor substrate, the hydrolyzable silane compound (B) is subjected to hydrolysis condensation on the surface of the substrate by moisture in the atmosphere to form a film of the diffusion agent composition on the surface of the semiconductor substrate. The hydrolyzable silane compound (B) has a high reaction rate in hydrolysis condensation, and thus can react with a small amount of moisture in a coating environment to form an extremely thin film during coating of the substrate; however, on the other hand, there is also a risk of reaction with water contained in the composition, allowing partial hydrolysis condensation before coating. In the diffusion agent composition according to the present invention, if the water content of the diffusion agent composition is below the upper limit, the hydrolysis condensation in the solution of the diffusion agent composition is suppressed to a minimum level, and a uniform and extremely thin coating film can thus be formed. As a result, the impurity diffusion component (A) can be expected to diffuse well.

### EXAMPLES

The present invention is described more specifically hereafter by way of Examples, which however should not be construed as limiting the present invention.

### Examples 1 to 4 and Comparative Examples 1 and 2

The following materials were used as components of the diffusion agent composition. Tri-n-butoxyarsenic (a 4 mass % solution of n-butyl acetate) was used as the impurity diffusion component (A). Tetraisocyanatesilane was used as the hydrolyzable silane compound (B). n-Butyl acetate was used as the organic solvent (S).

The impurity diffusion component (A), the hydrolyzable silane compound (B), and the organic solvent (S) were homogeneously mixed such that the solid content concentration was 0.6% by mass and the As/Si element ratio was 0.5, followed by filtering through a 0.2 μm pore diameter filter to thereby obtain a diffusion agent composition.

The amount of water contained in the diffusion agent composition was regulated by dehydration of the organic solvent (S) before mixing with a molecular sieve to obtain diffusion agent compositions of Examples 1 to 4 and Comparative Examples 1 and 2.

The above diffusion agent composition was coated on a surface of a silicon substrate having a flat surface (4-in., p-type) with a spin coater to form a coating film having a thickness of 4.5 nm.

Following the coating film formation, the diffusion treatment of the impurity diffusion component was carried out according to the following method.

First, the coating film was baked on a hot plate. Subsequently, the film was heated in a nitrogen atmosphere at a flow rate of 1 L/m at a temperature rise rate of 10° C./sec, using a rapid thermal annealing apparatus (MILA-3000, a lamp annealing apparatus) manufactured by ULVAC, Inc., to thereby diffuse under impurity diffusion conditions of a diffusion temperature of 1000° C. and a holding time of 1 min. After the completion of the diffusion, the semiconductor substrate was rapidly cooled to room temperature.

After the completion of the diffusion, the sheet resistance of a surface of a p-type silicon substrate, the surface having been subjected to diffusion treatment with the impurity diffusion component, was determined by a four probe method with a sheet resistance measuring device (Napson RG-200PV). The measured sheet resistance values are shown in Table 1. The diffusion state of the impurity diffusion component was determined from the measured sheet resistance values based on the following criteria.

Very Good: The sheet resistance value was not more than 500 ohms/sq.
Good: The sheet resistance value was more than 500 ohms/sq. (exclusive) to not more than 1,000 ohms/sq. (inclusive)
Fair: The sheet resistance value was more than 1,000 ohms/sq. (exclusive) to 1,300 ohms/sq. (inclusive).
Poor: The sheet resistance value was more than 1,300 ohms/sq. (exclusive).

TABLE 1

| | Water content of | | |
|---|---|---|---|
| | diffusion agent | | |
| | composition | Sheet resistance | |
| | (% by mass) | (ohm/sq.) | Evaluation |
| Example 1 | 0.033 | 1,100 | Fair |
| Example 2 | 0.015 | 714.0 | Good |
| Example 3 | 0.014 | 657.0 | Good |
| Example 4 | 0.002 | 340.6 | Very Good |
| Comparative | 0.064 | 1,600 | Poor |
| Example 1 | | | |
| Comparative | 0.051 | 1,470 | Poor |
| Example 2 | | | |

It is apparent from Table 1 that, when diffusion agent compositions of Comparative Examples 1 and 2 having a water content of more than 0.05% by mass are used, the sheet resistance value of the semiconductor substrate after the diffusion treatment is high, indicating that the impurity diffusion component is not well diffused.

On the other hand, it is apparent from Examples 1 to 4 that, when the water content of the diffusion agent composition is not more than 0.05% by mass, particularly not more than 0.015% by mass, the sheet resistance value of the semiconductor substrate is significantly low, indicating that the impurity diffusion component is well diffused.

### Examples 5 to 7

The following materials were used as components of the diffusion agent composition. Tri-n-butoxy arsenic (a 4 mass % solution of n-butyl acetate) was used as the impurity diffusion component (A). Tetraisocyanatesilane was used as the hydrolyzable silane compound (B). n-Butyl acetate was used as the organic solvent (S).

The impurity diffusion component (A), the hydrolyzable silane compound (B), and the organic solvent (S) were homogeneously mixed such that the solid content concentration was 0.40% by mass and the As/Si element ratio was 0.77, followed by filtering through a 0.2 μm pore diameter filter to thereby obtain a diffusion agent composition.

The amount of water contained in the diffusion agent composition was regulated by dehydration of the organic solvent (S) before mixing with a molecular sieve to obtain diffusion agent compositions of Examples 5 to 7.

The above diffusion agent composition was coated on a surface of a silicon substrate having a flat surface (4-in., p-type) with a spin coater to form a coating film of a thickness specified in Table 2.

Following the coating film formation, the impurity diffusion component was diffused by the following method.

First, the coating film was baked on a hot plate. Subsequently, the film was heated in a nitrogen atmosphere at a flow rate of 1 L/m at a temperature rise rate of 10° C./sec with a rapid thermal annealing apparatus (MILA-3000, a lamp annealing apparatus) manufactured by ULVAC, Inc., to thereby diffuse under impurity diffusion conditions of a diffusion temperature of 1000° C. and a holding time of 7 sec. After the completion of the diffusion, the semiconductor substrate was rapidly cooled to room temperature.

After the completion of the diffusion, the sheet resistance of a surface of a p-type silicon substrate, the surface having been subjected to diffusion treatment with the impurity diffusion component, was determined by a four probe method with a sheet resistance measuring device (Napson RG-200PV). The measured sheet resistance values are shown in Table 2. The diffusion state of the impurity diffusion component was determined from the measured sheet resistance values based on the following criteria.

Very Good: The sheet resistance value was not more than 500 ohms/sq.
Good: The sheet resistance value was more than 500 ohms/sq. (exclusive) to not more than 1,000 ohms/sq. (inclusive)
Fair: The sheet resistance value was more than 1,000 ohms/sq. (exclusive) to 1,300 ohms/sq. (inclusive).
Poor: The sheet resistance value was more than 1,300 ohms/sq. (exclusive).

TABLE 2

| | Water content of | Thickness | | |
|---|---|---|---|---|
| | diffusion agent | of coating | Sheet | |
| | composition | film | resistance | |
| | (% by mass) | (nm) | (ohm/sq.) | Evaluation |
| Example 5 | 0.005 | 6.0 | 442.0 | Very good |
| Example 6 | 0.001 | 4.5 | 728.0 | Good |
| Example 7 | 0.0004 | 4.3 | 498.0 | Very Good |

It is apparent from the above results that, when the water content of the diffusion agent composition containing tetraisocyanatesilane is not more than 0.05% by mass, the impurity diffusion component is well diffused even in shortening of the holding time at the diffusion treatment temperature from 60 sec to 7 sec in Examples 1 to 4.

### Examples 8 and 9

The following materials were used as components of the diffusion agent composition. Trimethyl borate was used as the impurity diffusion component (A). Tetraisocyanatesilane was used as the hydrolyzable silane compound (B). n-Butyl acetate was used as the organic solvent (S).

The impurity diffusion component (A), the hydrolyzable silane compound (B), and the organic solvent (S) were homogeneously mixed such that the solid content concentration was 1.42% by mass and the B/Si element ratio was 1.95, followed by filtering through a 0.2 μm pore diameter filter to obtain a diffusion agent composition.

The amount of water contained in the diffusion agent composition was regulated by dehydration of the organic solvent (S) before mixing with a molecular sieve to obtain diffusion agent compositions of Examples 8 and 9.

The above diffusion agent composition was coated on a surface of a silicon substrate having a flat surface (4-in., N-type) with a spin coater, and the coating was rinsed with the same dehydrated n-butanol as used in the diffusion agent composition to form a coating film having a thickness of 10.8 nm.

Following the coating film formation, the diffusion treatment of the impurity diffusion component was carried out according to the following method.

First, the coating film was baked on a hot plate. Subsequently, the film was heated in a nitrogen atmosphere at a flow rate of 1 L/m at a temperature rise rate of 25° C./sec, using a rapid thermal annealing apparatus (MILA-3000, a lamp annealing apparatus) manufactured by ULVAC, Inc., to thereby diffuse under impurity diffusion conditions of a diffusion temperature of 1100° C. or 1200° C. and a holding time specified in Table 3. After the completion of the diffusion, the semiconductor substrate was rapidly cooled to room temperature.

After the completion of the diffusion, the sheet resistance of a surface of a silicon substrate, the surface having been subjected to diffusion treatment of the impurity diffusion component, was determined by a four probe method with a sheet resistance measuring device (Napson RG-200PV), and, further, whether or not reversing from N-type to P-type had occurred was confirmed.

As a result, it was found that, for both diffusion treatment at 1100° C. and diffusion treatment at 1200° C., reversing from N-type to P-type occurred. The sheet resistance values after diffusion treatment are shown in Table 3.

TABLE 3

| | Water content of | | | |
|---|---|---|---|---|
| | diffusion agent | Diffusion | Holding | Sheet |
| | composition | temperature | time | resistance |
| | (% by mass) | (° C.) | (sec.) | (ohm/sq.) |
| Example 8 | 0.002 | 1100 | 10 | 7689 |
| Example 9 | | 1200 | 15 | 2016 |

It is apparent from the above results that, when the water content of the diffusion agent composition containing tetraisocyanatesilane is not more than 0.05% by mass, the impurity diffusion component is well diffused even in the use of a boron compound as the impurity diffusion component.

### Examples 10 to 12

The following materials were used as components of the diffusion agent composition. Tris(trimethylsilyl) phosphite was used as the impurity diffusion component (A). Methyltriisocyanatesilane was used as the hydrolyzable silane compound (B). n-Butyl acetate was used as the organic solvent (S).

The impurity diffusion component (A), the hydrolyzable silane compound (B), and the organic solvent (S) were homogeneously mixed such that the solid content concentration was 0.43% by mass and the P/Si element ratio was 0.45, followed by filtering through a 0.2 μm pore diameter filter to thereby obtain a diffusion agent composition.

The amount of water contained in the diffusion agent composition was regulated by dehydration of the organic solvent (S) before mixing with a molecular sieve to obtain diffusion agent compositions of Examples 10 to 12.

The above diffusion agent composition was coated on a surface of a silicon substrate having a flat surface (4-in., P-type) with a spin coater, and the coating was then rinsed with the same dehydrated n-butanol as used in the diffusion agent composition to form a coating film having a thickness specified in Table 4.

Following the coating film formation, the diffusion treatment of the impurity diffusion component was carried out according to the following method.

First, the coating film was baked on a hot plate. Subsequently, the film was heated in a nitrogen atmosphere at a flow rate of 1 L/m at a temperature rise rate of 25° C./sec, using a rapid thermal annealing apparatus (MILA-3000, a lamp annealing apparatus) manufactured by ULVAC, Inc., to thereby diffuse under impurity diffusion conditions of a diffusion temperature of 1000° C. or 1100° C. and a holding time specified in Table 4. After the completion of the diffusion, the semiconductor substrate was rapidly cooled to room temperature.

After the completion of the diffusion, the sheet resistance of a surface of a silicon substrate, the surface having been subjected to diffusion treatment of the impurity diffusion component, was determined by a four probe method with a sheet resistance measuring device (Napson RG-200PV), and, further, whether or not reversing from P-type to N-type had occurred was confirmed.

As a result, it was found that, for both diffusion treatment at 1000° C. and diffusion treatment at 1100° C., reversing from P-type to N-type occurred regardless of the holding time. The sheet resistance values after diffusion treatment are shown in Table 4.

TABLE 4

| | Water content | | | | |
|---|---|---|---|---|---|
| | of diffusion | Thickness | Diffusion | Hold- | Sheet |
| | agent | of coating | temper- | ing | resis- |
| | composition | film | ature | time | tance |
| | (% by mass) | (nm) | (° C.) | (sec.) | (ohm/sq.) |
| Example 10 | 0.002 | 4.2 | 1000 | 10 | 4376 |
| Example 11 | | | 1100 | 10 | 1450 |
| Example 12 | | 2.2 | 1000 | 1 | 1521 |

It is apparent from the above results that, when the water content of the diffusion agent composition containing methyltriisocyanatesilane is not more than 0.05% by mass, the impurity diffusion component is well diffused even in the use of a phosphorus compound as the impurity diffusion component.

What is claimed is:

1. A diffusion agent composition for impurity diffusion into a semiconductor substrate, the diffusion agent composition comprising:
an impurity diffusion component (A) and a silicon compound (B) represented by the following formula (1):
R₄₋ₙSi(NCO)ₙ (1)
wherein R represents a hydrocarbon group and n is an integer of 3 or 4,
the Si compound (B) is hydrolyzable to produce a silanol group, and
the water content of the diffusion agent composition is not more than 0.05% by mass.
